(19) United States
(12) Patent Application Publication
(10) Pub. No.: US 2013/0075718 A1
(43) Pub. Date: Mar. 28, 2013

(54) THIN FILM DOPED ZnO NEUTRON DETECTOR

(71) Applicants: Jeff E. Nause, Smyrna, GA (US); Eric Anthony Burgett, Woodstock, GA (US); Nolan Elmer Hertel, Norcross, GA (US); Ian Ferguson, Davidson, NC (US)

(72) Inventors: Jeff E. Nause, Smyrna, GA (US); Eric Anthony Burgett, Woodstock, GA (US); Nolan Elmer Hertel, Norcross, GA (US); Ian Ferguson, Davidson, NC (US)

(21) Appl. No.: 13/424,458

(22) Filed: Mar. 20, 2012

Related U.S. Application Data
(63) Continuation-in-part of application No. 13/050,435, filed on Mar. 17, 2011.
(60) Provisional application No. 61/314,845, filed on Mar. 17, 2010.

(51) Int. Cl. H01L 31/0296

(52) U.S. Cl. CPC H01L 31/0296
USPC 257/43

(57) ABSTRACT

A neutron detector having a scintillator layer comprising a thin film of doped zinc oxide is disclosed. The use of doped zinc oxide in such applications provides appliances and detectors that are rugged, tolerant to shocks and temperature variations, non-hygoroscopic, and suitable for outdoor applications.

### RELATED APPLICATIONS

This application claims priority to United States Provisional Patent Application Ser. No. 61/314,845, filed Mar. 17, 2010, and U.S. patent application Ser. No. 13/050,435, filed Mar. 17, 2011; and is a Continuation-In-Part of U.S. patent application Ser. No. 13/050,435, filed Mar. 17, 2011.

### BACKGROUND OF THE INVENTION

The present invention relates generally to neutron detectors. More specifically, the present invention relates to thin film doped ZnO neutron detectors that are highly efficient, portable, large volume detectors, and related technology which may be a suitable replacement for ³He tubes. Neutron detectors are used in various applications, including homeland security and border security, nuclear safety, among others. These detectors are used in freight terminals, border security stations, ports, weigh bridge stations, and contamination monitoring of nuclear waste. It has been found that using a thin film of doped zinc oxide (ZnO) as a scintillator layer within a neutron detector apparatus provides certain benefits and improvements over existing technology, as discussed hereinbelow.

A scintillation counter measures ionizing radiation. The sensor, called a scintillator, consists of a transparent crystal, usually phosphor, plastic (usually containing anthracene), or organic liquid that fluoresces when struck by ionizing radiation. A sensitive photomultiplier tube (PMT or light sensor) measures the light from the crystal. The PMT is attached to an electronic amplifier and other electronic equipment to count and possibly quantify the amplitude of the signals produced by the photomultiplier.

### Scintillation Detector Theory

When radiation passes through matter it loses energy through ionization events. The amount of energy required to produce an ion-electron pair is known as the work function. Once ionized, atoms need to de-excite, that is, lose their charge. Gas-filled tube and semiconductor detectors directly collect the charge by means of a high voltage field which sweeps the charge out. Scintillation detectors, in contrast, allow the atoms or molecules of the scintillator to de-excite in the detector material. Materials that are classified as insulators or semiconductors have electron energy bands where electrons can exist. There are two primary bands, the lower valence band and the upper conduction band. The valence band is formed by electrons bound at lattice sites of the crystalline structure, while the conduction band consists of electrons which have enough energy to migrate through the crystalline structure. The forbidden zone, where electrons cannot reside, lies between the valence band and the conduction band.

In addition to the valence and conduction bands, doped scintillators possess activator sites which consist of acceptor and donor bands. When a scintillator relies on the energy difference between the conduction and valence bands, the recombination efficiency is typically low and results in a photon far outside the visible range in the deep UV spectrum. A standard band diagram for a semiconductor scintillator is shown in FIG. 5. Excited nuclei also exhibit a number of energy states in the immediate vicinity of the conduction and valence bands. This is due to the thermal energy in the system. The vibrational states add a small variation in the gap energy. This contributes to the broadening of the scintillation fluorescence peak.

In a traditional inorganic doped scintillator, such as NaI(Tl), LiI(Eu), or CsI(Tl), electrons can drift through the lattice until they encounter an acceptor location. Some of the ionized electrons can de-excite by dropping into acceptors and by releasing their excess energy in quanta of light, the energy of which is less than the band gap between the valence and conduction bands. This process can be relatively slow due to the long migration times between ionization and de-excitation. However, most electrons deposit their energy into the crystalline lattice non-radiatively as phonons of heat. The different kinds of radiation emitted in nuclear reactions—gamma, scattered electrons, alpha and beta particles, protons, and fission fragments—carry energy from tens of keV to tens of MeV. Using the approximation of a 3 eV work function, a 1 MeV particle will produce ˜3.3×10⁵ the ionization events. If the de-excitation time is a Poisson distribution, very long decay times on the order of tens to hundreds of microseconds are possible. Not all of the excitation events emit optical light pulses. Some electrons fall into traps created by crystalline defects, contaminants in the crystal, and phonon de-excitation. In undoped inorganic scintillators, such as ZnO, BaF, and CsI, the electron preferentially de-excites locally, since there are no activator sites. This produces a very fast scintillation pulse at a large photon energy in the UV range. The band gap in these structures allows electrons to directly de-excite across the band gap.

Electrons in organic scintillators may de-excite anywhere along the molecular chain. Organic scintillators are usually faster than inorganic scintillators for this reason. Organic scintillators usually have a benzene ring structure to exploit its singlet and triplet decay modes. The scintillation spectrum of organic scintillators is significantly broader than that of inorganic scintillators due to the number of different singlet and triplet bands, the intersystem crossing of the bands, and the overlapping π-orbital bonds. The number of available de-excitation bands is higher in organic scintillators, which enables higher luminosities than in inorganic scintillators.

The scintillation wavelength of light depends directly on the band gap scheme of the material. Whereas wide band gaps generate short UV scintillation pulses, small band gaps generate long wavelength scintillation pulses closer to green wavelengths. Most scintillator's de-excitation fluorescence wavelengths are in the near UV to blue wavelengths. Longer wavelengths usually result in longer pulse decay times, as exhibited in NaI(Tl) and LaBr₃. This is due to the longer mean lifetime of the electron resulting from the elevated temperature of scintillator material, and the electron's ability to reach more shallow acceptor locations. Without donors or acceptors, a scintillator produces light at the band gap wavelength. Near the band gap transition, the transmission of light is negligible, and the index of refraction is very high. Consequently, to produce large-volume scintillators like those used in gamma radiation detection, acceptors and donors are added to produce scintillation photon emissions at longer wavelengths that are not immediately absorbed by the scintillator.

During evaluation of new scintillation materials, the scintillation spectrum and the efficiency of the light collection system must be taken into consideration. Scintillation light is collected through one or many light conversion tools. Currently, the photomultiplier tube (PMT) is the principal technology for scintillation light collection. Other systems, such as avalanche photodiodes (APDs), show high promise for PMT replacement.

### Fundamental Properties

Pure zinc oxide has a room temperature bandgap of 3.37 eV, an exciton binding energy of 60 meV and is optically transparent in the wavelength range between 320 and 2500 nm. This II-VI semiconductor has been studied for many optoelectric applications, including LEDs, solar cells, and laser diodes. Pure ZnO has optical transparency ranging from 380 to 2500 nm. The exciton binding energy of ZnO is twice that of GaN (28 meV). Interest in ZnO has grown recently due to its large photo response and tunable luminescence properties that can be induced by doping or alloying. Alloying ZnO films with MgO and CdO permits the bandgap to be engineered from 2.3 to 4.0 eV. As a consequence of its large exciton binding energy, the exciton transition remains dominant in optical processes even above room temperature, giving ZnO an advantage over other inorganic scintillators for exciton—related device applications. Also, this characteristic results in the ZnO scintillator having a temperature invariant luminescent (scintillator) response up to 500 C. Additionally, the higher exciton binding energy of ZnO at room temperature enables fast electron hole recombination during scintillation, and the probability of electron trapping is reduced compared to other scintillator materials. This also prevents the ZnO scintillator from having a significant temperature coefficient. By alloying ZnO with MgO and CdO the bandgap can be tuned between 2.8 and 6.1 eV, which facilitates bandgap engineering. Measurements indicate an intrinsic rise time of 30 ps and a decay time of 0.65 ns.^{iv} These response times are faster than all other organic or inorganic scintillators currently available commercially.^{v} These ultrafast rise and fall times allow this scintillator to perform well in high count rate environments.

Thus, the fundamental properties of ZnO are ideal for scintillator applications—the material has an unprecedented fast, 30 ps risetime, sub nanosecond decay times and emits a 310 nm wavelength photon. In addition to their ultrafast performance, high light yield ZnO scintillators can be grown in large crystalline geometries. Also these scintillator materials are non toxic, non volatile, non hygroscopic, durable and rugged and are grown using environmentally friendly materials with no hazardous byproducts created in the process. Additionally, ZnO can be doped with lithium and/or additional coatings of lithium can be evaporated on its surface.

A new neutron detector with properties that meet or exceed the performance of ³He tubes is needed. It is hypothesized that zinc oxide (ZnO) scintillators, doped with neutron sensitive materials and wavelength shifting materials and, potentially, improved via a photonic crystal structure, can serve as the thermal neutron detector to replace ³He. A matrix of six metrics was tested against standard neutron detectors to evaluate the novel ZnO scintillator as a neutron detector. These included neutron detection efficiency, neutron versus gamma discrimination, scintillation wavelength, scintillation speed, optical clarity, and ease of growth/size of the detector. Detection efficiencies and gamma discrimination capabilities will be tested against standard neutron detectors such as ³He tubes and lithiated glass scintillators.

### Extrinsic Properties of ZnO

Previous Work on ZnO Scintillators (1950s-60s)

ZnO is a promising inorganic crystal for application as a scintillator for thermal neutron detection. ZnO was originally investigated in the 1950s and 1960s along with ZnS. At the time this was the only form of this material available as large crystal growth had not been achieved. In the early 1990s, interest in zinc oxide returned as researchers began searching for more efficient ultraviolet LEDs. In this effort the search for p-type ZnO laid the groundwork for developing efficient scintillators.

In the 1960s, Lehmann explored the use of donor impurities in semiconducting ZnO and prepared Ga doped ZnO powder for scintillation applications; today, many different dopants such as Gd, B and Li are also possible. It was proposed by Lehmann that the substitution of Zn atoms with Ga introduces a degenerate donor band overlapping the bottom of the conduction and. In addition to creating more electrons than Zn when ionized by high energy radiation, electrons in the donor band recombine with ionization generated holes in the valence band, resulting in near band edge light emission and decay times less than 1 ns. However, comparatively the luminosities were low, since the scintillation properties were measured in powder material; however, with the recent advances in crystal growth technology (melt growth and MOCVD) ZnO scintillation properties can be dramatically improved by producing large diameter single crystals or large single crystal thin films. Additionally, by doping or coating the ZnO crystal with neutron target nuclei, an ultrafast scintillator capable of detecting neutrons with high efficiency can be realized. ZnO crystals as well as lithium, gadolinium and boron doped ZnO crystals can currently be grown in boules up to 2 inches in diameter and 2 inches in length (Cermet, Inc) or as 2 inch wafers by MOCVD (Georgia Tech). Cermet, Inc. is a commercial vendor of ZnO bulk crystals and has successfully grown up to 10 weight percent Li doped ZnO single crystals for scintillator applications.

Large single crystals have been grown by Cermet, Inc. and include low pitch etch density and absences of grain boundaries. Thin scintillators may be grown through the melt growth and MOCVD process. ZnO scintillators have been doped with various transition metals to assess the impact on light yield. Initial testing showed that although the crystals were very small they performed well as a neutron scintillator, and exhibited intrinsically low response to gamma rays due to their small thickness. The results of these tests are shown below in FIGS. 3 and 4. While these detectors did show a non negligible response to gamma rays in comparison to the neutrons, the PuBe neutron source used for this initial test produces a very hard neutron energy. However, the thermal neutron detectors do exhibit quite a different response when exposed to thermal neutrons. The cross section at fast neutron energies is very low (less than 1%). In contrast at thermal energies, the lithium content and additional ⁶Li coating increase the response of the scintillator through the (n,α) reaction. The lithium doped scintillator was tested with an alpha particle source of similar energy to that of the (n,α) particle reaction in ⁶Li. Excellent discrimination between alpha particles and gamma ray events was observed. This detector was found to have an 87.6% intrinsic efficiency for detecting the alpha particles.

### ZnO Scintillators

### Introduction to ZnO

Many different impurities, such as Ga, B, and Li, may be used for scintillation applications. Lehmann hypothesized that substituting Zn atoms with Ga atoms would introduce a degenerate donor band overlapping the bottom of the conduction band and would result in greater electron production from ionization by high energy radiation. Donor band electrons recombine with ionization holes in the valence band. This results in near band edge emission with a decay time of less than 1 ns. The luminosities were comparatively low, since the scintillation properties were measured in materials in powder form. However, ZnO scintillation properties can be dramatically improved by producing single crystals, due to recent advances in crystal growth technology. An ultrafast scintillator capable of efficiently detecting neutrons can be realized by doping or coating the ZnO crystal with neutron target nuclei. Traditionally “doping” refers to semiconductor dopant levels up to 0.1% atom fractions. In this discussion, however, dopant quantities can refer to atomic compositions up to 10% atom fraction.

Measurements with ZnO: In scintillators indicate a pulse FWHM of ˜0.65 ns compared to that of a fast plastic scintillator with a pulse FWHM of ˜1 ns—faster than all other organic and inorganic scintillators. The ZnO scintillator has a rise less than 1 ns compared to a BC-408 plastic scintillator with a rise time of ˜1.5 ns. Ultrafast rise and decay times allow scintillators to perform well in high count rate environments.

Zinc oxide can exist in three crystalline forms, a hexagonal wurzite structure, a cubic zincblende, and a rare zinc rocksalt. It can also exist in an amorphous form. The rocksalt phase forms when it is alloyed or when the growth pressure is increased. It is preferable to use wurzite ZnO over zincblende for many reasons, including stability at room temperature and ease of growth. ZnO wurzite phase has lattice constants of A=3.25 and C=5.2 with a C/A ratio of ˜1.6—a nearly perfect lattice for a hexagonal structured material (C/A ratio of 1.6333). Zinc oxide however is tolerant to growth on a variety of different materials. Depending on the orientation of the substrate, seed crystal, or lack thereof, different ZnO orientations can be achieved.

Zinc oxide, however, is a relatively soft material with a Mohs hardness scale value of only 4.5, comparable to window glass which has a Mohs hardness of 5.5. It is resistant to most solvents and water, but can be etched by strong bases and acids. It is thermally stable to 1975° C., at which temperature it will begin to decompose. Above 800° C. in an atmosphere with oxygen it will accept oxygen and fill any zinc vacancies. The wurzite and zincblende structures do not possess inversion symmetry (the reflection of the structure becomes the structure), and, consequently, these structures possess a high piezoelectricity. Wurzite ZnO's piezoelectricity is enhanced by its largely ionic bonds. Future work, for example, could exploit the piezoelectric effect for other novel radiation detection methods such as piezoelectric nanorod arrays or thin films.

Zinc oxide is a transparent crystal with a relatively low index of refraction in the visible region. The index of refraction near the band edge rises above 3 due to its band gap. In the optical wavelengths, however, its index of refraction is ˜1.9

Zinc oxide crystals can be doped with a number of different nuclei. Several n-type dopants exist, predominantly, Group III elements, such as Ga and Al. Recent research has focused on the search for p-type dopants. P-type material, or semiconductor material which is rich in acceptor locations, is difficult to achieve in ZnO. P-type dopants are mostly from Group I nuclei such as Li, Na, K, and Group V, such as N. ZnO can be doped with neutron detecting target nuclei such as boron and lithium. This provides a unique opportunity to produce new neutron detectors.

### Growth Techniques

Several growth mechanisms are exploited. The first is a melt growth process and the second is a thin film metalorganic chemical vapor deposition (MOCVD) method. Two inch diameter boules of scintillator grade ZnO can be routinely grown using the melt growth method and with additional effort, boules can be grown up to six inches in diameter. Also thin film scintillators can be grown by MOCVD on ZnO or alternate substrates such as Al₂O₃ and SiO₂ with a high throughput.

### Radiation Detection Performance

It is calculated that doped ZnO scintillators can have intrinsic detection efficiencies approaching 100% for thermal neutrons; higher than ³He tubes of comparable dimensions. In addition, by using thin scintillators, the gamma ray response can be almost completely eliminated since very little recoil electron energy is deposited in the scintillator compared to the alpha particle. Initial investigations of this concept have shown gamma discrimination on the pulse height was obtained by simple voltage discrimination. Superior performance compared to ³He counterparts has been observed in the pulse rise time and efficiencies for thermal neutrons. Excellent gamma ray discrimination has been measured, comparable to that of existing ³He detectors. In pulsed active interrogation systems, these scintillators are far superior to current ³He tubes. They are nearly blind to gamma radiation and have one of the fastest pulse rise and fall times of any scintillator known currently. The performance can be further enhanced by fabricating a doped ZnO photonic crystal. Additionally, it is contemplated that photonic crystals may be used to enhance light yield by increasing the spontaneous emission rate of optical photons from excited scintillator materials, and to control the directional emission of light, constraining light to propagate along localized channels. This near term ³He replacement detector system can be integrated with avalanche photodiodes to produce low voltage systems. Such a scintillator/detector system may be up to six inches wide, less than 1 mm thick, and arrayed to cover surface areas of more than 10⁴ cm². These scintillators are considerably cheaper to fabricate than ³He tubes of comparable surface areas, with mass production costs estimated to be less than those currently available.

### BRIEF SUMMARY OF THE INVENTION

In accordance with one aspect of the invention, a thin film doped ZnO neutron detector is disclosed, and is highly efficient, portable, and includes large volume detector capacity to replace ³He tubes. The invention does provide a superior replacement for ³He counters with added spectroscopic capability such as utilizing the Q value of the target nucleus or using moderator materials such as polyethylene. The detector includes a large area, ultrafast, thermal neutron scintillator based on ZnO with ⁶Li ¹⁰B or Gd coatings and/or Li, ⁶Li, B, or ¹⁰B doped scintillators such as ZnO:Li, ZnO: ⁶Li ZnO:B, ZnO: ¹⁰B ZnO:Gd, etc. This invention is made possible by improved growth techniques for these materials that optimize the efficiency of the scintillator materials and light yields.

New spectroscopic capabilities can be added to the detection system by coupling a doped or coated ZnO scintillator with a unique moderator configuration to provide neutron energy sensitivity. These radiation detector designs enable field deployable spectroscopic detectors that are superior to current ³He tube systems. These devices can be packaged on a single device with an avalanche photodiode or photomultiplier tube. The unique properties of ZnO make this material an excellent choice for many of the proposed applications and demonstrations. The present invention is thus directed to neutron detection system utilizing doped ZnO in a thin film form grown by melt growth or particularly MOCVD.

### BRIEF DESCRIPTION OF THE DRAWINGS

These and other features, aspects, and advantages of the present invention will become better understood with regard to the following description, appended claims, and accompanying drawings where:

FIG. 1 is a graph indicating experimental neutron response of undoped ZnO. Responses are shown for a ⁶⁰Co spectrum and PuBe neutrons. This sample is undoped ZnO with and without a polytheylene.

FIG. 2 includes two graphs, (a) and (b) wherein (a) indicates the speed of response of a BC408 plastic scintillator and, (b) Li-doped ZnO scintillator, wherein time divisions in (a) are 5 ns per major division and in (b) are 1 ns/major division.

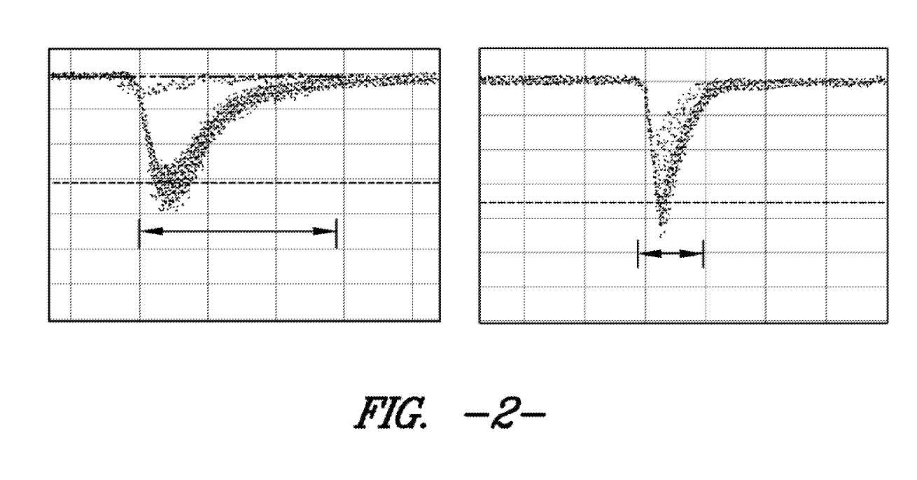

FIG. 3 is a graph indicating experimental neutron response of lithium doped ZnO crystal to PuBe neutrons. Responses are shown for ⁶⁰Co gamma rays and neutron response spectra. The dopant levels are 0.1% by mass ⁶Li.

FIG. 4 is a graph indicating experimental response of Li-doped ZnO scintillator to alpha particles of similar energy to that of the ⁶Li (n,α) reaction.

FIG. 5 is a graph indicating (n,α) spectra resulting from neutrons on the lithium doped ZnO scintillator. Also shown is an alpha spectra for comparison to a pure alpha emitter. Neutron versus gamma ray discrimination is easily achieved using a simple low voltage discriminator.

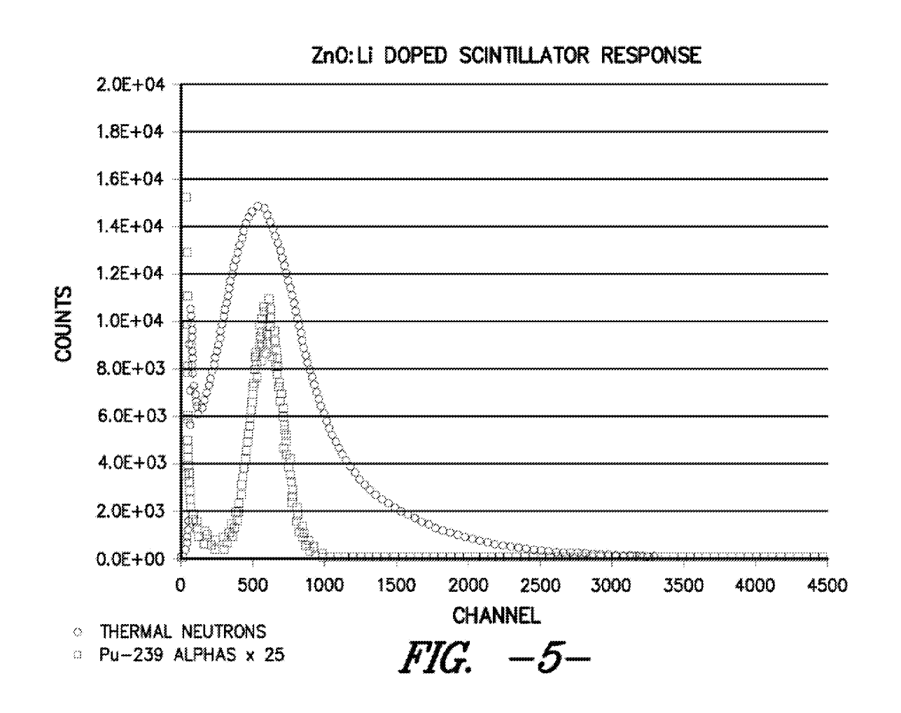

FIG. 6 is a graph indicating computed Li-doped ZnO spectroscopic neutron detector responses for the system shown in FIG. 5.

FIG. 7 is a graph indicating one possible configuration for producing a ZnO spectrometer using varying thicknesses of polyethylene moderators over large-area, doped ZnO crystals.

FIG. 8 is a graph indicating energy loss profile for gamma rays, electrons and alpha particles.

### DETAILED DESCRIPTION OF THE INVENTION

ZnO is a radiation scintillating inorganic crystal with significant advantages over other scintillating materials, namely ultrafast rise and fall times and can be doped to enhance both optical and scintillator properties.

### Device Implementation

Despite their excellent characteristics, the performance of ZnO scintillators is compromised by the fact that they exhibit a characteristic absorption of scintillation generated light at wavelengths below 320 nm. Since ZnO scintillates at 310 nm, the scintillator will reabsorb its own emitted light. This issue can be overcome by creating a thin scintillator crystal, so that the scintillation generated light only propagates a short distance before escaping. ZnO scintillator crystals less than 0.1 mm thick are very rugged and allow collection of a large fraction of their scintillation generated light and have been grown by MOCVD up to two inch diameters. The thin size is also beneficial as it reduces the gamma ray response of the scintillator, since the secondary electron ranges exceed the crystal thickness.

The second method for increasing the light yield out of the scintillator is by introducing dopants into the crystal during growth, the luminescent transition between conduction band electrons and valence band holes can be moved to lower energies or longer wavelengths. By manipulating this band gap, the atomic excitation can then be controlled resulting in optimal wavelength emission. By incorporating donor band states such as gallium or indium, the luminescence can be tuned to a lower energy such that the emission of the doped material is moved to longer wavelengths ZnO is transparent. Using MOCVD technique a range of detector crystals has been grown to test variations in dopant levels on light transmission, light yield, and decay mode/decay times. Optimizing the balance between the concentration of lithium in the ZnO crystal and tuning the scintillator emission does yield a scintillator that possesses the ultrafast timing properties of ZnO while obtaining high thermal neutron efficiencies.

Scintillators have been produced and tested using ZnO crystals with Gd, B, ⁶Li or Li combined into the ZnO matrix during growth and/or ZnO crystals coated with Gd B, and Li or ⁶Li by using evaporation and diffusion techniques after growth. This not only functions as a neutron detector but also a neutron spectrometer utilizing the full energy deposition of both charged particle fragments and observing the energy in excess of the Q value. A second design for producing a neutron spectrometer incorporates a polyethylene proton radiator used with an undoped ZnO scintillator. In this system, the ZnO scintillator is sensititized to higher energy neutrons by using the recoiling protons from the hydrogen in the polyethylene to produce ionization events in the undoped ZnO scintillator. Both of these designs have been grown and tested with favorable results.

Large planar configurations are possible with this system, unlike ³He tubes, which are spherical or cylindrical in shape. The doped ZnO planar detector configuration has a substantially higher intrinsic efficiency, approaching 100% for a wider band of energies. As previously mentioned, the designs are making use of thin crystals, thereby reducing the gamma ray response.

### Technology of ZnO Crystal Growth

ZnO single crystals have been grown (Cermet, Inc.) in a high pressure induction melting apparatus, wherein the melt is contained in a water cooled crucible. An RF heat source is used during the melting operation. Induced fields in the charge material produce eddy currents, which produce joule heating in the material until a molten phase is achieved. The highly refractory melt produced is contained in a cold wall crucible by a solid thermal barrier that forms between the molten material and cooler material of the same composition. The cooled material prevents the molten material from directly contacting the crucible cooling surface. The entire melting process is carried out in a controlled gas atmosphere ranging from 1 atm to over 100 atm. This prevents the loss of volatile components, as well as the decomposition of compounds into atomic species. ZnO can be grown in 8 inch diameter crucibles, producing kilogram mass boules from which inch sized single crystals.

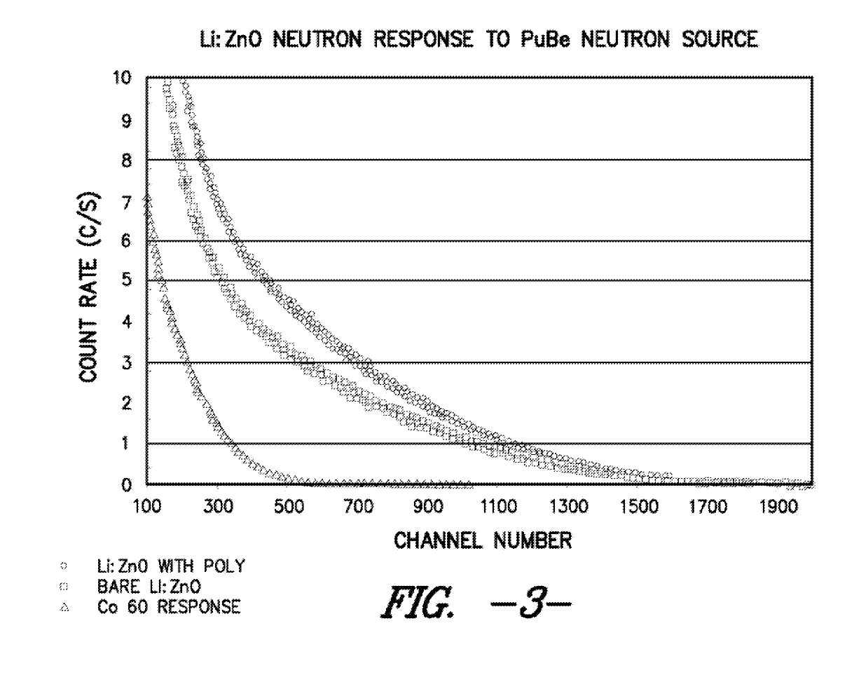

A 2 inch ZnO boule accompanied by an optical micrograph indicating low etch pit density is shown in FIG. 3. Cermet's growth process allows for in situ doping of almost any practical dopant with relative ease. Because of the band gap enhancement in addition to the high thermal neutron cross section, lithium and gadolinium are the principal dopants investigated, but are not limited to just these; any charged particle producing reaction can be used. This work has achieved up to 10 weight percent dopant in the crystal. In addition, coating the surface of the scintillators with Li or Gd through evaporation and diffusion techniques have been investigated as possible pathways to producing a thermal neutron sensitive detectors.

The second growth method, the MOCVD process allows for tighter control over dopant levels and thicknesses as well as growth on different substrates and conformal coatings of these scintillators. This system is ideal for test runs of various growth parameters such as dopant concentrations and surface treatments. This rapid prototyping system has been exploited in the first phase of the project to develop an optimal scintillator composition for neutron detection.

### ZnO Growth

### Crystal Growth

There are a number of different crystal growth methods for ZnO scintillators. They are broken into two distinct groups, bulk growth and thin film/nanoparticle growth. Bulk growth can be divided into melt growth, hydrothermal growth, Seeded Chemical Vapor Transport (SCVT), Chemical Vapor Transport (CVT), and Chemical Vapor Deposition (CVD) growth. Each growth method was pioneered by a primary commercial company.

SCVT growth is primarily performed by Eagle Pitcher, which has reported growth rates of 40 μm per hour in a horizontal tube furnace at 1000-1200° C. This company uses a zinc source and hydrogen as a carrier gas with an overpressure of water vapor to maintain stoichiometry. In this process, the crystal is seeded by an initial ZnO crystal, and grows on a 5.08 cm (2 in) diameter. The growth rate for this method, however, is constrained and asymptotically approaches a steady state value lower than the 40 μm per hour. Doping, which requires a suitable source capable of sublimation to the gas phase, is difficult with this method.

Chemical Vapor Transport is similar to SCVT, but there is no seed crystal to nucleate growth. This method usually has a lower crystalline quality due to the random nature of the initial growth. However, it is a low-cost option to produce bulk materials. Using a standard horizontal tube furnace, the growth is conducted by sublimation of zinc under a hydrogen carrier gas. Oxygen or water is used as the other reagent, while monitoring the partial pressure of carrier gas and reactant gases.

CERMET, Inc., is the leader in bulk melt grown materials. CERMET utilizes a patented crystal growth technology, cold wall bulk melt growth at high pressure, to produce doped and undoped ZnO single crystals. An RF heat source induces fields in the starter ZnO material in the water-cooled cold wall chamber. These fields produce eddy currents, which promote Joulean heating in the material until it melts. The highly refractory melt is contained in a cold wall crucible by a solid thermal barrier that forms between it and the molten material. The cooled material prevents the molten material from directly contacting the crucible cooling surface. This entire melting process is carried out in a controlled gas atmosphere ranging from 1 atm to over 100 atm. This prevents the loss of volatile components, as well as the decomposition of compounds into atomic components. CERMET has melted ZnO in 6 inch diameter crucibles, producing kilogram-sized boules from which inch-sized single crystals were cut.

Hydrothermal growth of ZnO consists of a solution using LiOH, NaOH or KOH as a solvent at very high pressures (150 ATM+) and a temperature less than 400° C. Zinc oxide is dissolved under extreme conditions and then allowed to precipitate slowly out of solution as the pressure/temperature is reduced. This growth rate is exceptionally slow (mm per day), and the ZnO contains high concentrations of contaminant nuclei from the solvent. However, there has been a report of exceptional crystalline quality with a full width half maximum (FWHM) of 8 arc seconds in the XRD plot.

Each method described above has been investigated for nearly twenty years. While hydrothermal growth has produced the best reported crystalline quality, it incorporates contaminants undesirable for scintillation applications. Melt growth provides the highest speed and largest boules of usable scintillation material. Melt growth also shows the most promise for doping with neutron target materials and allows for in situ doping of almost any practical dopant with relative ease. While it is possible to grow at high growth rates by CVT and SCVT, the cost of fabrication of materials by these methods tend to be prohibitive. Inability to dope the materials makes these methods unsuitable for the fabrication of scintillation detectors.

### MOCVD Growth

One promising growth mechanism for ZnO is by Metalorganic Chemical Vapor Deposition. MOCVD is an epitaxial growth method of chemical vapor deposition in which the alkyl precursors are attached to an organic molecule. Metalorganics are usually volatile pyrophoric liquid materials, which aid in the growth process. Special growth reactors are required for MOCVD crystal growth and can grow various materials including GaN, GaAs, InP, and ZnO. Subtle changes to the internal components of these reactors enable application of different precursors. The change required to accommodate different growth materials is costly and time consuming, as the tool is disassembled and rebuilt. MOCVD permits very fine control of the structure and dopant levels, and can produce a very uniform epitaxial layer.

The heater is capable of rapid temperature changes and can operate in vacuum as well as extreme environments, such as oxidizing or reducing atmospheres. Different designs of reactors have been proposed over the years. However, the most common one in mass production is the rotating disk model. The rotating disk spins under a shower head, from which the metalorganic precursor is introduced. The growth chamber's pressure may vary between 0.1 and 100 Torr and for ZnO growth low pressure growth is preferable. The design relies on a stable reactor condition in which laminar flow is maintained over the growth platter. Significant effort is put into designing the vessel head to achieve laminar flow. As the metalorganic precursor is heated, it is cracked, breaking the hydrogen and carbon nuclei and leaving the free metal ion in the gas phase flow. A reactant gas is then flowed simultaneously or in pulsed mode over the growth platter. The reactant gas completes the other half of the compound semiconductor.

In multicomponent semiconductors, several alkyl sources and reactant gases can be pulsed or flowed into the chamber. For example, in ZnO growth, diethylzinc is the metalorganic of choice, and either oxygen (O₂), nitrous oxide (N₂O), or nitrogen monoxide (NO) can be used as the reactant gas. Ideally, oxygen or nitrous oxide are typically the best choices. These two gas molecules crack to form free oxygen. Nitrous oxide also produces N₂, which is stable and is not incorporated into the matrix. N₂ is the common carrier gas that is flowed into the growth chamber to maintain laminar flow over the substrate for this very reason. Nitrogen monoxide, however, when cracked leaves free nitrogen. This free nitrogen is absorbed readily into the matrix resulting in nitrogen doped samples. The reaction for ZnO MOCVD growth using oxygen as the gas can be seen in the Equation below. MOCVD growth of ZnO is one of the few completely green reactions producing safe, non-toxic gases as byproducts.

(C₂H₅)₂Zn+7O₂→ZnO+5H₂O+4CO₂

Dopant gases are ideally metalorganic liquids similar to diethylzinc. Trimethylgallium (TMGa), trimethylindium (TMIn), and diethylboron are frequently used for gallium, indium, and boron doping, respectively. These metalorganics are sometimes too efficient at doping in comparison to the zinc oxide growth. Metalorganic sources are highly volatile, as many have boiling points below 10° C. In ZnO MOCVD, nitrogen (carrier gas) is flowed through the liquid source. The flow rate of a metalorganic through the reactor is determined by partial pressures of the carrier gas and the source through a bubbler. The composition and doping of a material is precisely controlled by varying the source temperatures, the carrier gas flow, and the partial pressures. Bypass lines are often installed to minimize the pressure differential in the bubbler. This allows rapid switching at both constant pressure and constant flow rate between the metalorganic source and carrier gas to minimize spiking in the doping profile.

A series of mass flow controllers, solenoid valves, and pressure controllers/transducers regulates the gas flow of the carrier gas, reactant gas, and the metalorganic sources. Vacuum is maintained by a high volume, high vacuum pump, which usually includes a two stage vacuum/blower configuration. The internal chamber pressure is regulated on the exhaust side through a digitally controlled exhaust butterfly valve. Temperature and rotation measurements are performed with a resistive thermal detector (RTD) and a pyrometer (for operation above 700° C.) and an optical RPM meter. Computer control of MOCVD components ensures precise determination of the growth conditions.

Characterization tools can be integrated into the MOCVD chamber: For example, surface reflectance and ellipsometry. Surface reflectance is measured using a fiber optic wide band light source to direct light into the growth chamber and measure the reflected light from the surface of the rotating wafer.

The measurements are gated on the rotational speed of the wafer so as to only measure the reflectance of the wafer and not the spinning platter. For ZnO, one full oscillation at 730 nm light corresponds to ˜250 nm of growth.

This in-situ characterization technique is crucial for optimizing the growth parameters such as chamber pressure effects on growth, growth rates, dopant levels and optical quality. The status of the crystal growth process can be easily monitored without the need to stop the reaction, cool the chamber, and bring the chamber back to atmospheric conditions.

Two dimensional (2D) thin film growth generates highly uniform films with very few defects at high growth rates and requires a specific range of growth conditions. In contrast, 3D film growth gives rise to nanorod-like structures and polycrystalline materials, which are impractical for application in scintillators. The crystalline defects and grain boundaries produce trapping locations, longer scintillation decay times, and scintillation outside the band gap. ZnO growth in the MOCVD process has a very narrow window in which 2D growth can occur and is especially sensitive to the reactor pressure (between 10 and 50 Torr). Outside this region, the metalorganic preferentially adheres to the surface and does not diffuse into a smooth 2D growth. 2D growth requires a reactor temperature between 475° C. and 550° C. Above 550° C., the growth rate is reduced below 100 nm/h. Below 475° C., a sufficient quantity of oxygen cannot be cracked. By switching oxygen precursor gases may improve this requirement. Hybrid 2D and 3D ZnO has also been grown.

The crystal quality of the MOCVD grown ZnO samples is heavily dependent on the substrate, although ZnO offers significant tolerance to strain the first few layers. Ideally, the lattice mismatch between the substrate and the ZnO structure should be minimized. Sapphire is the preferred growth substrate with a lattice mismatch parameter of approximately 30%. However, despite the large lattice mismatch, ZnO can compensate for it within the first 100 Å, promoting high quality 2D growth. ZnO has been grown on other substrates, including silicon, silicon oxide, and glass. High quality films can be grown on almost any material including non-wurzite structures and amorphous materials by utilizing techniques described in the following section.

### Radiation Detection Performance of ZnO Neutron Response

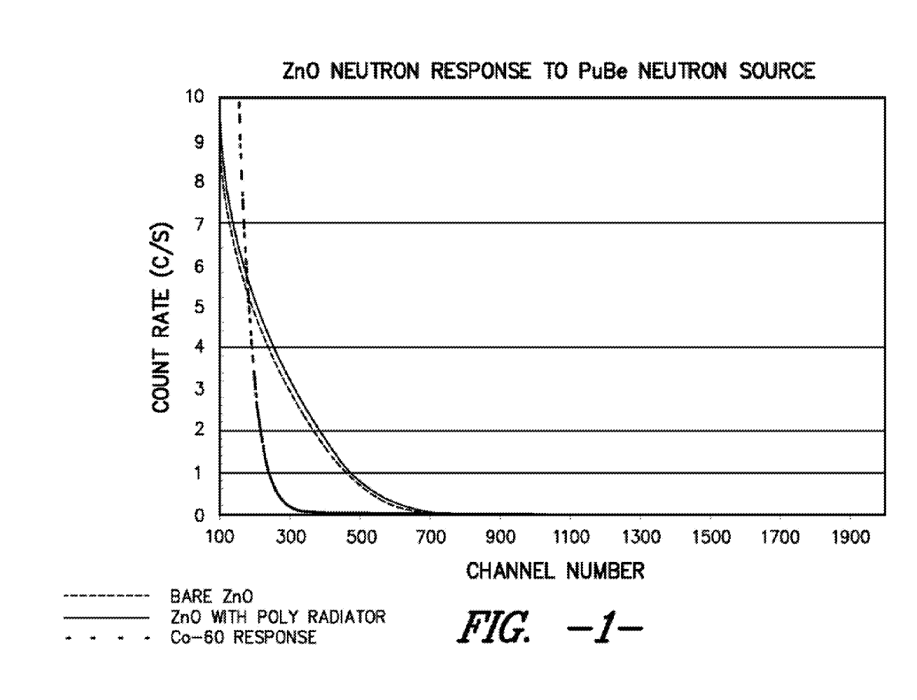

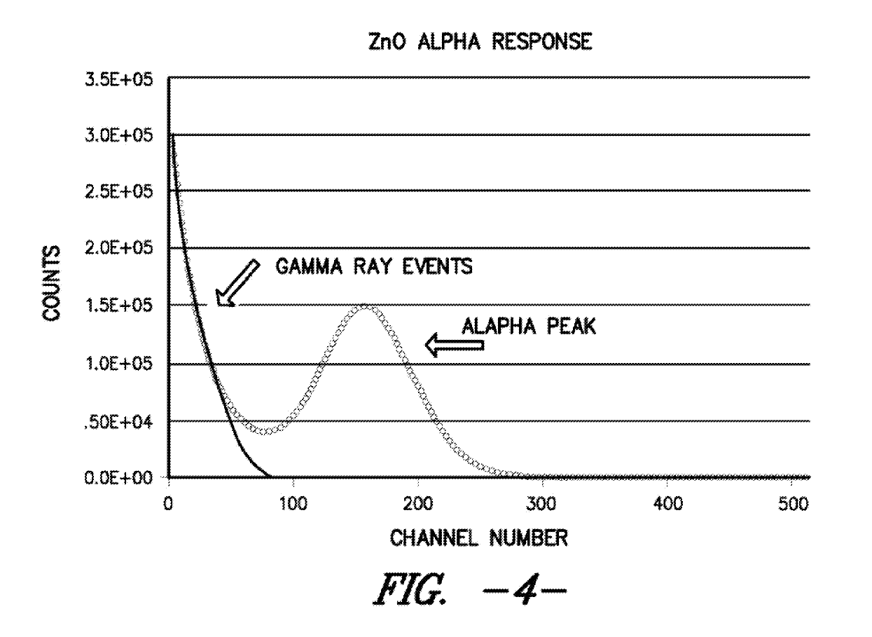

A 1 cm×1 cm×5 mm thick undoped ZnO crystal was tested in a neutron field and a ⁶⁰Co gamma ray field. The pulse height distribution of the undoped ZnO scintillator to ⁶⁰Co gamma rays is shown in FIG. 1 along with the response to PuBe neutrons with and without the incorporation of a polyethylene radiator. A 1 cm×1 cm×0.1 mm lithium-doped crystal (0.1%) was also tested with both sources. Also measurements were taken of a lithium-doped ZnO scintillator after incorporating a 1 cm thick, high density polyethylene radiator (FIG. 4). The lithium-doped ZnO crystal shows an increase in pulse height response, which is attributed to the thermal neutron reactions in the natural lithium present in the scintillator. Thus, doped crystal improves the detection of neutrons and the use of the polyethylene radiator further increases the response due to the moderation of high energy neutrons. Note the volume of the doped scintillator is 1/50^{th}, nearly two orders of magnitude, smaller than the volume of the undoped scintillator, and the integrated count rate of the doped crystal when exposed to the PuBe source was 5000 times greater than that of the undoped ZnO scintillator; an amplification of approximately 250,000. Since the lithium doped scintillator contains only 0.1% natural lithium by mass and it is possible to grow 10% lithium by mass crystals, the potential of this system is apparent. Thus, in principal an amplification of 2.5×10⁶ is possible. It is estimated that the potential of ZnO detectors developed have efficiencies at 87% absolute efficiency for thermal neutrons. In contrast the current efficiencies of ³He tubes are ^{˜}41% for thermal neutrons based on a 10 atm fill gas pressure.

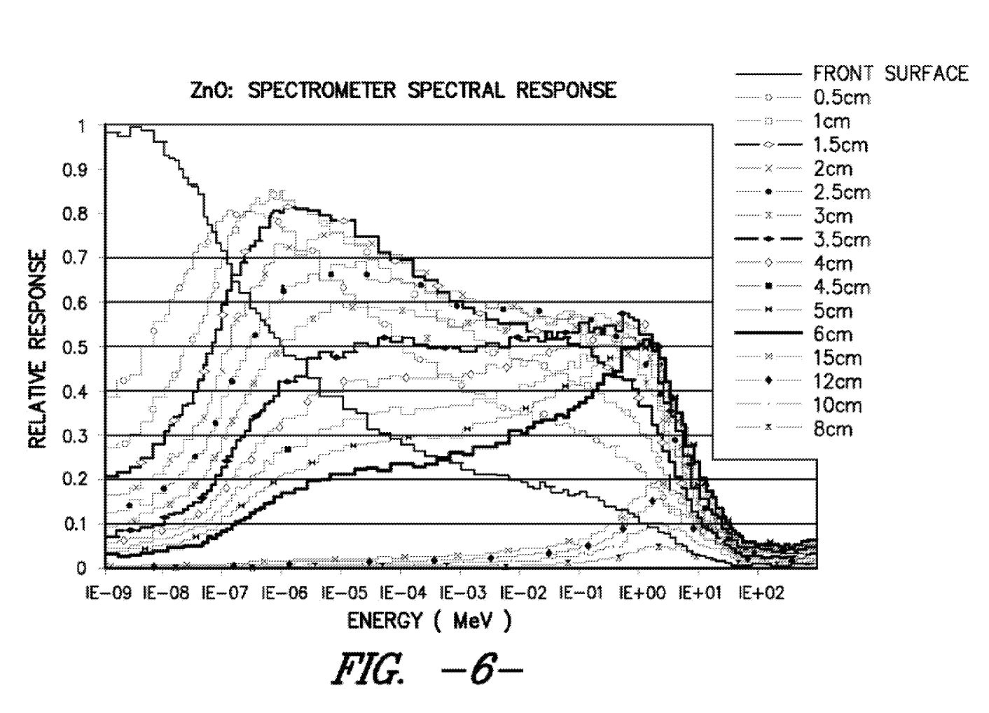

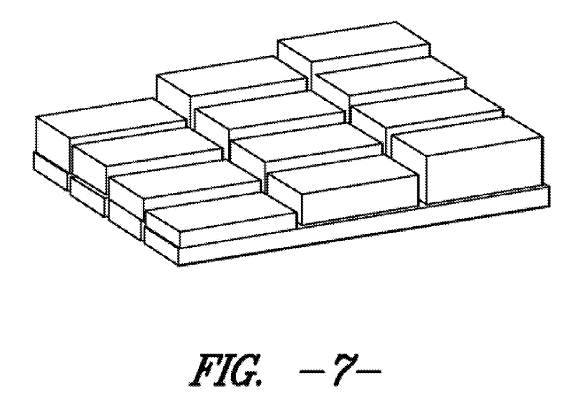

ZnO has the added benefit that it can be titled to form large surface area planar arrays unlike ³He tubes raising the ZnO scintillators effective detection area. Both doped and undoped ZnO crystals tested exhibited a significantly different pulse height distribution for neutrons and gamma rays (FIGS. 3 and 4). If these devices were incorporated with varying thicknesses of polyethylene moderator in order to moderate and capture detectors, an energy sensitive, large area neutron detector could be created (FIGS. 6 and 7). This method is described below. With the ultrafast properties of the crystal, the development of a large area neutron spectrometer could be developed with fast timing capabilities.

### Gamma Ray Response

The gamma ray response of a ZnO scintillator can be minimized by using thin crystals. Due to the large absorption cross section of the Li or Gd dopants and surface treatments and the short ranges associated with the secondary particles, the ZnO scintillator's neutron detection capabilities are largely a surface or near surface interaction phenomena. Therefore, the use of the thin crystals permits gamma ray discrimination to be achieved by setting a low level discriminator on the outcoming pulses.

### ZnO Neutron Spectroscopic Capabilities

An additional extension of the capabilities of the ZnO scintillators can be used to create neutron spectrometers by using moderators. Two possible avenues exist. Undoped ZnO can be coupled to a polyethylene proton radiator to create a proton recoil telescope. This approach could be used to produce neutron spectrometers with high spectral resolution but with low efficiencies. A more straightforward approach is to use doped ZnO scintillators in a moderate and capture detector design, as shown in FIG. 7. In this approach, the scintillators would be surrounded by varying thicknesses of polyethylene. By using a large slab detector, a low resolution neutron spectrometer can be constructed. The slab detector may be an array of ZnO crystals. This system may be used in fast timing applications due to the ultrafast rise time of ZnO. The count rates from several doped ZnO detectors within the slab, which would have various thicknesses, could be combined to produce a low resolution neutron spectrum. The possibility also exists for using fast electronics to perform the neutron spectrum deconvolution in real time. A calculation describing the spectral response of a stepped slab moderate and capture system is shown in FIG. 7. Investigations of different combinations of moderator thicknesses may lead to a better optimized system than the one shown in that section.

### Potential System Applications

ZnO structures are rugged, even when less than 1 mm thick. They are tolerant to shocks and temperature variations, they are non hygroscopic, and they are suitable for outdoor applications. Since these devices are not gas filled tubes, they are not sensitive to microphotonics and are made from non hazardous materials in an environmentally friendly manner. The raw materials are easily available and a substantial commercial fabrication process exists. Using avalanche photodiodes in place of Photomultiplier Tubes (PMTs), a very low (<50V) operating voltage detection system can be created. The temperature sensitivity of the ZnO scintillator is low for operating temperatures anticipated to be encountered in the deployment of detection system. This is a result of the wide band gap and scintillation emission wavelength of 310 nm.

### Technical Implementation

A three step approach has been accomplished. The first step was to develop the ultrafast lithium Boron, Gadolinium doped and/or coated ZnO scintillator. The scintillator is constructed with thicknesses from 4-10 microns (the range of alpha particles in ZnO). The ZnO crystals are grown on a transparent double polished sapphire substrate. A highly enriched ⁶Li or Gd layer has been evaporated onto the exterior surface of the ZnO crystal to enhance its efficiency for neutron detection or incorporated into the crystal itself or both. During the first phase of the project, the potential of using the ZnO scintillator with a proton radiator has been investigated with an ultrafast proton recoil telescope in mind. The inclusion of this polyethylene radiator does extend energy range of neutron detection beyond thermal energies. In the doped ultrafast ZnO neutron scintillator has been incorporated in a large area moderator system to produce a high efficiency neutron spectrometer. A planar moderator design allows for large detection surface area with directional sensitivity. Similar to other moderate and capture detector designs such as a Bonner Sphere Spectrometer, varying thicknesses of polyethylene is used to produce differing levels of moderation. The first version of such a spectrometer to be investigated uses a stepped slab polyethylene moderator (see FIG. 7 as an example) to produce the different levels of moderation required for varying neutron energy sensitivity. Other designs include randomizing the moderator thickness, using coded aperture designs to further incorporate energy information or lastly continuum based designs including sine, cosine, and hyperbolic shapes to maximize the number of unique energy shapes. Through the use of multiple scintillators, such a system has a high efficiency, ultrafast signal, and produces a large area neutron spectrometer. Data collection systems for the spectral deconvolution can be used for both a real time system, such as an FPGA based system, and an offline deconvolution program.

This invention provides an immediate solution to a national need. Increasingly ³He is becoming very scarce and because current demand far outweighs production, a near term replacement is needed. Doped ZnO scintillator crystals provide a low cost, near term replacement for ³He detectors. The ZnO scintillator is not only rugged, but also an easily fabricated, environmentally friendly material which can outperform ³He in many applications. Thus, the invention offers a near term replacement to ³He tubes by the use of optimally doped ZnO scintillators and also by the use of undoped or doped ZnO scintillators that use a photonic crystal structures to improve thermal neutron detection efficiencies. Further designs are the construction of a neutron spectroscopic solution for high energy neutron detection by incorporating a polymer layer.

Unlike ³He tubes which are cylindrical or spherical in shape, ZnO based scintillators can be made into large planar arrays with efficiencies that equal or surpass ³He. These low cost scintillators are made from readily available materials in an environmentally friendly process, can be mass produced, and can provide additional capabilities not currently available with existing systems. The ZnO scintillator can improve the national ability to detect illicit nuclear materials particularly in both a passive and active setting. Passive neutron detection yields nearly no gamma ray background response while in active mode, the benefits are numerous. Active interrogation systems can benefit from the ultrafast timing properties of the scintillator with sub nanosecond rise and fall times, along with its gamma discrimination capabilities. These systems make it easier to detect prompt neutron emission from active interrogation systems due to the low dead time and ultrafast response. The improvement over current ³He systems is lower operating voltages, faster responses, larger areas, higher efficiencies, lower cost, more rugged, non hygroscopic durable detectors which are made from non toxic environmentally friendly materials and are available in the near term. This system addresses every need for a near term replacement solution.

One advantage of the ZnO scintillator system is that is an ultra fast thermal neutron scintillator. It has been calculated to have nearly 100% thermal neutron detection efficiency and a very low gamma ray response. Initial calculations and preliminary experimental tests prove the idea to be sound and feasible. Experimental devices have shown greater than 85% efficiencies and nearly no gamma ray response. This system is capable of meeting the need for a near term ³He replacement.

### Relevance and Outcomes/Impacts

The work shown here is centered on the design, construction and optimization of a near term replacement for large ³He tubes. The resulting outcome is a large area thermal neutron detector system. This near term solution is produced from environmentally friendly materials and results in a scintillator detector that is superior to current systems. The impact of this research will lower the cost of operation of new neutron detector systems through more rugged robust designs. These systems will also yield the ability to create detectors that are more efficient, faster, and larger area at a lower cost. This lower cost allows for more detectors to be purchased covering larger areas. The larger area more efficient detectors will lower the minimum detectable quantities of neutron emitting materials in a wide range of applications.

Large area ZnO thermal neutron scintillators may be used as a near term replacement for ³He. Research has been conducted into optimizing the growth and dopant concentrations of the scintillators through the MOCVD process. Optimized moderator designs are used to produce a spectroscopic neutron detector.

Research into lithium and boron dopant levels has been the primary focus to achieving the high light yields of the ZnO scintillator. While lithium and boron concentrations improve neutron detection, they also decrease the light yield. To compensate, bandgap tuning using various dopants such as gallium has been researched to improve light yield and light transmission. Improved light collection techniques and pulse processing systems have been investigated to improve the efficiency and timing resolution of the systems designed. Radiation testing investigations have tested the pulse height and efficiency of the doped scintillators in relation to current thermal neutron detector systems including a reference ³He tube. Mass production using MOCVD is possible using the currently designed system which has a direct commercialization route. Neutron modeling has been performed to optimize the detector system. Spectroscopic unfolding programs have been created to unfold the incident neutron spectra.

### Claims Overview

A composite integrated neutron detector consisting of a neutron to alpha particle converter layer, a scintillator layer that has a very large spatial discrimination between alpha particles and gamma rays and electrons.

Neutrons interact either in a doped scintillator, or conversion material to produce one or more charged particles. This can be a material such as ⁶Li, ¹⁰B, Gd, Hf, U, Pu, Th or N. These charged particles have very short ranges, (typically less than 10 um) and very high energies (100's of keV to 10s of MeV). These particles interact in the scintillator matrix surrounding the conversion materials producing electron hole pairs. The electron hole pairs recombine in the semiconductor scintillator material to produce optical photons. These optical photons are collected through an avalanche photodiode, photomultiplier tube or other suitable photon to electron conversion/amplification material. To improve light collection and the spontaneous light emission of optical photons, a photonic crystal structure can be employed in the scintillator matrix.

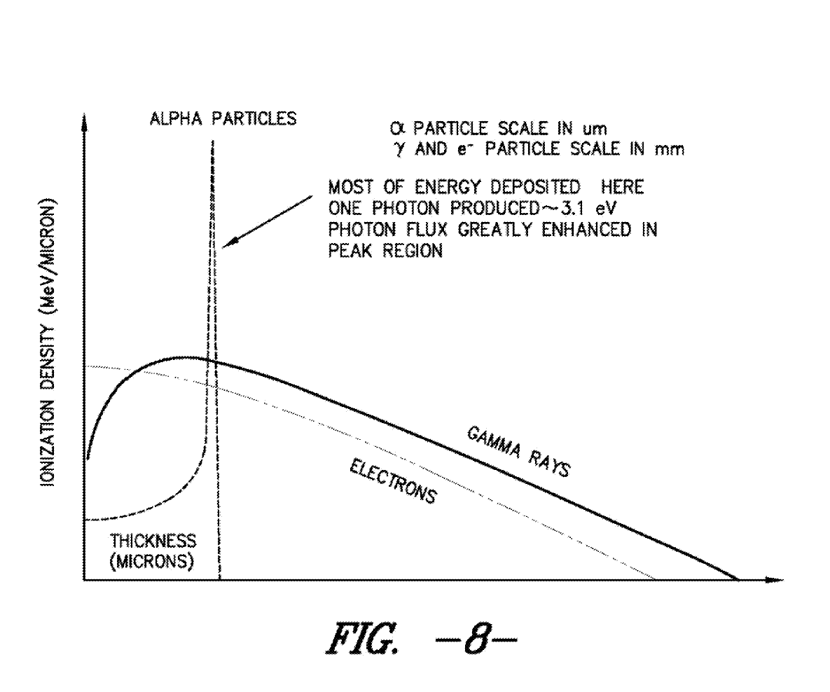

To discriminate gamma rays from neutrons, advantage is taken of the fact that the energy loss profile for alphas and other heavy charged particles generated from neutron interactions are orders of magnitude shorter (stopping power orders of magnitudes larger) than for gammas ray. By harnessing this difference, neutron versus gamma discrimination is achieved. After amplification of the light signal by the PMT, APD, or similar device, the signal can be further amplified through a preamp amp system. After amplification, the signal is digitized. The peak of the pulse height is recorded in specialized software. The pulse height distribution is directly proportional to the number of optical photons collected by the PMT, APD or similar device. The number of optical photons collected is proportional to the amount of energy imparted into the scintillator. By the physics of the engineered scintillator structures, the energy deposition rate of the electrons produced from gamma ray interactions in the packaging and scintillator itself have been minimized. At the same time, the energy deposition for the charged particles produced from neutron interactions in the above specified target nuclei have been maximized. Simple low level discrimination techniques can be employed to achieve neutron versus gamma discrimination. Since gamma ray interactions deposit orders of magnitude less energy in the scintillator than the charged particles produced from neutron interactions with the target nuclei, the pulse height distribution shows a clear separation of neutron interactions from gamma ray interactions. This acts as a spatial discriminator—essentially the energy loss profile of alphas occur over ^{˜}5 m while the energy loss of gamma rays and electrons is so long that they essentially pass through the detectors and deposit negligible energy. FIG. 8 shows energy loss profile in which the energy loss increases exponentially with distance as shown.

This is accomplished by taking advantage of the fact in films such as Li, B, Gd, Hf, and the like, the energy loss profile for alphas particles is orders of magnitude shorter (stopping power orders of magnitudes larger) than for their gammas rays or electrons. This property is used as a spatial discriminator—essentially the energy loss profile of alphas occur over ^{˜}5 m while the energy loss of gamma rays and electrons is much greater, >5 mm such that they pass through the detection region without depositing much energy.

Potential Applications

Other potential applications include the following:

A spatial discriminator between an alpha and gamma and electrons can be achieved.

The creation of electron hole pairs and their subsequent recombination to form photons of energy equal to, or slightly lower, than the bandgap of the semiconductor scintillator (ZnO, GaN, ZnS).

A spatial discriminator between and alpha and gamma rays and electrons such that the energy loss profile has the form shown in FIG. 8. Essentially the energy loss profile increases exponentially with distance and then drops precipitously such that most of the scintillated light is emitted in a narrow band at the end of the alpha particle range.

The creation of electron hole pairs and their subsequent recombination to form photons of energy equal to, or slightly lower than the band gap of the semiconductor (ZnO, ZnS) scintillator.

A device structure consisting of a Li or B layer to convert neutrons to alpha and gamma and electrons placed on top on a scintillator material; such as ZnO, GaN, GaAs, InP or ZnS.

A scintillator material which provides a large spatial discrimination between the electron hole distribution generated by decaying alpha particles and gamma and electrons, such that the alpha particles generate a e h and photo distribution very close to the surface.

A photonic crystals layer placed at the peak of the energy loss curve to control the generation emission and directionality of scintillator photons.

Large planar devices can be made using this method. These devices can be layered with repeating layers of scintillator, target nuclei, scintillator, target nuclei, etc. to improve the overall detector efficiency.

A polyethylene, hydrogenous material, carbon, beryllium, heavy water, or other moderator material can be placed over the neutron detector, or around the neutron detector to improve the detection efficiency to higher energy neutrons. This effectively creates a moderate and capture neutron detector with large planar areas.

A neutron spectrometer utilizing the above moderate and capture structure can be created by varying the thickness of the moderator surrounding the neutron scintillator structure.

A neutron spectrometer can be created by utilizing the Q value of the neutron to charged particle production reaction. Due to the small size of the scintillator structures which are engineered, the energy can be collected from all of the charged particles produced in the reaction. Knowing the energy of all of the resulting particles, and the Q value of the reaction, the incident neutron energy can be determined mathematically. By measuring the peak location in the pulse height distribution, the incident neutron energy can be determined.

A low voltage, low power radiation detector can be created using APDs or PMTs.

A light weight portable radiation detector can be created using these thin scintillators.

A large array that can be tiled to produce a two dimensional plane radiation detector.

Volume radiation detector consisting of vertically stacked 2D arrays of ZnO scintillators.

What is claimed is:

1. A neutron detector comprising:
an electronic light sensor; and
a scintillator operatively connected to said electronic light sensor, wherein said scintillator includes a scintillating layer comprising zinc oxide doped with material selected from the group consisting of Gd, B, Li, ⁶Li, and ¹⁰B.

2. The neutron detector set forth in claim 1, wherein said zinc oxide is formed into a crystal that is less than 0.1 mm thick.

3. The neutron detector set forth in claim 1, wherein said scintillator is operatively connected to a converter layer for converting neutrons to alpha particles.
